(19) United States
(12) Patent Application Publication
(10) Pub. No.: US 2024/0284597 A1
(43) Pub. Date: Aug. 22, 2024

(54) DRIVE UNIT AND ELECTRICALLY ASSISTED BICYCLE

(71) Applicant: YAMAHA HATSUDOKI KABUSHIKI KAISHA, Iwata-shi (JP)

(72) Inventors: Satoshi KATAYAMA, Shizuoka (JP); Hirokazu ISOBE, Shizuoka (JP); Shota UDA, Shizuoka (JP)

(21) Appl. No.: 18/442,423

(22) Filed: Feb. 15, 2024

(30) Foreign Application Priority Data
Feb. 20, 2023 (JP) 2023-024007

(51) Int. Cl. H05K 1/14; B62M 6/55; B62M 6/80; H05K 1/02

(52) U.S. Cl. CPC H05K 1/147; B62M 6/55; B62M 6/80; H05K 1/023

(57) ABSTRACT

A drive unit for an electrically assisted bicycle includes an electric motor, a housing accommodating a portion or an entirety of the electric motor, a pedal crank shaft extending through the housing and rotatably supported by the housing, a transmission to transmit a torque of the electric motor, a rigid board including an electric circuit to cause the electric motor to operate, and a flexible printed circuit to electrically connect the rigid board and another predetermined component in addition to the rigid board to each other.

### CROSS REFERENCE TO RELATED APPLICATIONS

This application claims the benefit of priority to Japanese Patent Application No. 2023-024007 filed on Feb. 20, 2023. The entire contents of this application are hereby incorporated herein by reference.

### BACKGROUND OF THE INVENTION

### 1. Field of the Invention

The present invention relates to drive units and electrically assisted bicycles.

### 2. Description of the Related Art

Bicycles are widely used by a variety of people regardless of age or gender as easy-to-use means of transportation. Recently, electrically assisted bicycles, by which power of users performing pedaling is assisted by electric motors, are increasingly common (see, for example, Japanese Laid-Open Patent Publication No. 2014-196080). Such an electrically assisted bicycle causes an electric motor to generate drive power corresponding to the power of a human body, specifically, the power provided by a user to a pedal, and thus alleviates the load imposed on the user while, for example, running on a slope or running with a cargo.

The electrically assisted bicycle includes a drive unit including an electric motor and the like. Known drive units include a drive unit of a type located in a hub of a rear wheel and a drive unit of a type attached to a bottom end of a vehicle frame (in the vicinity of a bottom bracket). Recently, the latter type of drive unit is becoming mainstream.

The electrically assisted bicycle disclosed in Japanese Laid-Open Patent Publication No. 2014-196080 includes a drive unit attached to a bottom end of a vehicle frame. The drive unit includes a housing, an electric motor, a pedal crank shaft and the like.

The electric motor is accommodated in the housing, and generates drive power that assists the pedal effort of the rider. The pedal crank shaft extends through the housing in a left-right direction of the vehicle. Pedals are attached to the pedal crank shaft via arms. The rotation of the pedal crank shaft is transmitted to the rear wheel via a drive sprocket, a chain, a driven sprocket and the like.

### SUMMARY OF THE INVENTION

In an electrically assisted bicycle, various components need to be located in a limited space in the vehicle. If the drive unit is large, the components in the vicinity of the drive unit are restricted in the positional arrangement thereof. The drive unit itself is also restricted in the positional arrangement thereof. Therefore, the size of the drive unit is required to be decreased.

In order to decrease the size of the drive unit, it is desired to increase the degree of freedom of the positional arrangement of components in the drive unit.

Example embodiments of the present invention disclose drive units and electrically assisted bicycles as described below.

A drive unit usable in an electrically assisted bicycle includes an electric motor, a housing accommodating a portion or an entirety of the electric motor, a pedal crank shaft extending through the housing and rotatably supported by the housing, a transmission to transmit a torque of the electric motor, a rigid board including an electric circuit to cause the electric motor to operate, and a flexible printed circuit to electrically connect the rigid board and another predetermined component in addition to the rigid board to each other.

According to an example embodiment of the present invention, the rigid board including the electric circuit to cause the electric motor to operate and the predetermined component are electrically connected with each other by the flexible printed circuit. In general, the flexible printed circuit is thinner than, and has a higher degree of freedom of bending than, a round wire. The rigid board and the predetermined component are electrically connected with each other by the flexible printed circuit, and therefore, may be positionally arranged in the housing with a higher degree of freedom. In addition, the other components may also be positionally arranged in the housing with a higher degree of freedom.

The flexible printed circuit, which is used as a wire, is not twisted or bent unlike a round wire, has a large dimensional tolerance. Therefore, the space required for the wire may be made smaller, and thus the drive unit may be smaller.

In a drive unit according to an example embodiment, the predetermined component includes an external device connector electrically connecting the drive unit and an external device to each other, and the flexible printed circuit electrically connects the rigid board and the external device connector to each other.

With this structure, the rigid board and the external device connector may be positionally arranged in the housing with a higher degree of freedom.

In drive unit according to an example embodiment, the predetermined component includes another rigid board in addition to the rigid board, and the flexible printed circuit electrically connects the rigid board and the another rigid board to each other.

With this structure, the plurality of rigid boards may be positionally arranged in the housing with a higher degree of freedom.

In a drive unit according to an example embodiment, one of the rigid board and the another rigid board is a power supply circuit board including a power supply circuit to output electric power to drive the electric motor, and the other of the rigid board and the another rigid board is a control circuit board including a control circuit to control an operation of the power supply circuit.

The control circuit may be located far away from the power supply circuit, which generates a large amount of heat. This may improve the stability of the control of the operation of the electric motor, and permit the power supply circuit to generate a larger amount of heat.

The power supply circuit board and the control circuit board are electrically connected with each other by the flexible printed circuit, and therefore, may be positionally arranged in the housing with a higher degree of freedom.

In a drive unit according to an example embodiment, the control circuit board is smaller than the power supply circuit board.

The control circuit board may be located in a relatively small space in the housing. The power supply circuit and the control circuit are included in separate boards so that relatively small spaces in the housing may be effectively used.

In a drive unit according to an example embodiment, the predetermined component includes an external device connector electrically connecting the drive unit and an external device to each other, the drive unit further includes another rigid board in addition to the rigid board, another external device connector in addition to the external device connector, and another flexible printed circuit in addition to the flexible printed circuit. The flexible printed circuit electrically connects the rigid board and the external device connector to each other, and the another flexible printed circuit electrically connects the another rigid board and the another external device connector to each other.

The external device connector and the flexible printed circuit, each of which tends to be enlarged in the case of having many functions in a single body, are divided into a plurality of portions, so that each of such portions of the external device connector and the flexible printed circuit may be smaller and located in a smaller space in the housing.

In a drive unit according to an example embodiment, one of the rigid board and the another rigid board is a power supply circuit board including a power supply circuit to output electric power to drive the electric motor, and the other of the rigid board and the another rigid board is a control circuit board including a control circuit to control an operation of the power supply circuit.

The external device connector and the flexible printed circuit for the control circuit board may easily be made smaller and each located in a relatively small space in the housing. Therefore, relatively small spaces in the housing may be effectively used.

A drive unit according to an example embodiment further includes a reinforcing plate between the flexible printed circuit and the external device connector in a thickness direction of the flexible printed circuit, at a location where the flexible printed circuit and the external device connector are stacked on each other.

A connector is not used to connect the flexible printed circuit and the external device connector so that the thickness of the connection portion of the flexible printed circuit and the external device connector may be decreased.

Use of the reinforcing plate may increase the strength of the connection portion of the flexible printed circuit and the external device connector.

A drive unit according to an example embodiment further includes a reinforcing plate on a surface of the flexible printed circuit opposite to a surface of the flexible printed circuit connected with the external device connector in a thickness direction of the flexible printed circuit, at a location where the flexible printed circuit and the external device connector are stacked on each other.

Use of the reinforcing plate may increase the strength of the connection portion of the flexible printed circuit and the external device connector.

In a drive unit according to an example embodiment, the external device connector includes pins extending through the reinforcing plate.

With this structure, the flexible printed circuit and the external device connector may be electrically connected with each other with no wire bypassing the reinforcing plate.

The pins of the external device connector extend through the reinforcing plate so that the reinforcing plate may be reduced or prevented from being positionally shifted.

In a drive unit according to an example embodiment, the flexible printed circuit and the external device connector are electrically connected with each other by at least one of solder, an anisotropic conductive film, or an anisotropic conductive paste.

The flexible printed circuit and the external device connector are directly mounted on each other with no use of a connector connecting the flexible printed circuit and the external device connector to each other so that the thickness of the connection portion of the flexible printed circuit and the external device connector may be decreased.

A drive unit according to an example embodiment further includes a noise suppressor on the flexible printed circuit.

The flexible printed circuit is used as a wire so that the noise suppressor may be easily located on the wire at such a position as to effectively reduce or prevent noise. This may decrease the number of the noise suppressors to be located on the rigid board, and also decrease the size of the rigid board.

In a drive unit according to an example embodiment, the reinforcing plate is a rigid board provided with a noise suppressor.

With this structure, the connection portion of the flexible printed circuit and the external device connector may have an increased strength and also improved tolerance against noise.

An electrically assisted bicycle according to an example embodiment of the present invention includes a drive unit including any of the features described above.

The drive unit is smaller so that the components around the drive unit may be positionally arranged in the electrically assisted bicycle with a higher degree of freedom.

According to an example embodiment of the present invention, the rigid board including the electric circuit to cause the electric motor to operate and the predetermined component are electrically connected with each other by the flexible printed circuit. In general, flexible printed circuits are thinner than, and have a higher degree of freedom of bending than, round wires. The rigid board and the predetermined component are electrically connected with each other by the flexible printed circuit, and therefore, may be positionally arranged in the housing with a higher degree of freedom. In addition, the other components may also be positionally arranged in the housing with a higher degree of freedom.

Flexible printed circuits, which are used as wires, are not twisted or bent unlike round wires, have a large dimensional tolerance. Therefore, the space required for the wires may be smaller, and thus the drive unit may be smaller.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a right side view of an electrically assisted bicycle 10 according to an example embodiment of the present invention.

FIG. 2 is a cross-sectional view showing an internal structure of a drive unit 20 included in the electrically assisted bicycle 10 according to an example embodiment of the present invention.

FIG. 3 shows an example of boards and wires according to an example embodiment of the present invention.

FIG. 4 shows an example of internal structure of the drive unit 20, in which the boards the wires are located according to an example embodiment of the present invention.

FIG. 5A shows an external device connector 130, a reinforcing plate 150, and a flexible printed circuit 120a according to an example embodiment of the present invention, and FIG. 5B shows the external device connector 130 and the flexible printed circuit 120a connected to each other with the reinforcing plate 150 being held therebetween.

FIG. 6A shows the external device connector 130, the flexible printed circuit 120a, and the reinforcing plate 150 according to an example embodiment of the present invention, and FIG. 6B shows the reinforcing plate 150 located on a surface of the flexible printed circuit 120a opposite to a surface of the flexible printed circuit 120a connected with the external device connector 130.

FIG. 7 shows an example of a method to connect the external device connector 130 and the flexible printed circuit 120a to each other, different from those shown in FIGS. 5A-6B, according to an example embodiment of the present invention.

FIG. 8 shows the reinforcing plate 150 provided with a noise suppressor 125 according to an example embodiment of the present invention.

FIG. 9 shows another example of the flexible printed circuit 120 and the connectors 130 according to an example embodiment of the present invention.

### DETAILED DESCRIPTION OF THE EXAMPLE EMBODIMENTS

Hereinafter, drive units and electrically assisted vehicles including the drive units according to example embodiments of the present invention will be described with reference to the drawings. In the description of the example embodiments, like components will bear like reference signs, and overlapping descriptions will be omitted. In the example embodiments of the present invention, “front”, “rear”, “left”, “right”, “up” and “down” respectively refer to “front”, “rear”, “left”, “right”, “up” and “down” based on a state where a rider is sitting on a saddle (seat) of the electrically assisted vehicle while facing a handle. In the drawings, letters F, Re, L, R, U and D respectively indicate front, rear, left, right, up and down. The following example embodiments are merely illustrative, and the present invention is not limited to the following example embodiments in any way.

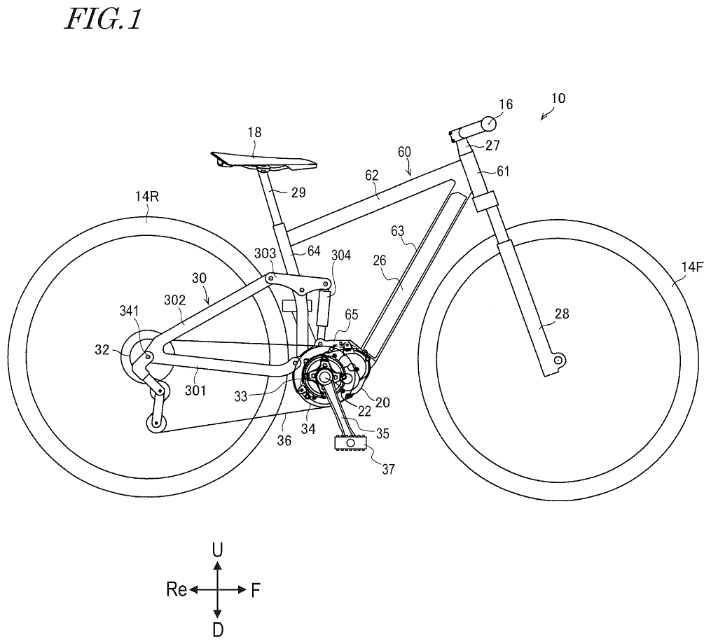

With reference to FIG. 1, an electrically assisted bicycle 10 as an example of electrically assisted vehicle according to an example embodiment of the present invention will be described. FIG. 1 is a right side view generally showing a structure of the electrically assisted bicycle 10.

The electrically assisted bicycle 10 includes a vehicle frame 60, a front wheel 14F, a rear wheel 14R, a handle 16 and a saddle 18. The electrically assisted bicycle 10 further includes a drive unit 20 and a battery unit 26.

The vehicle frame 60 includes a head tube 61, a top tube 62, a down tube 63, a seat tube 64, and a bracket 65.

The head tube 61 is located in a front portion of the vehicle frame 60, and extends in an up-down direction. A stem 27 is rotatably inserted into the head tube 61. A handle 16 is secured to a top end of the stem 27. A front fork 28 is secured to a bottom end of the stem 27. The front wheel 14F is rotatably attached to a bottom end of the front fork 28. Namely, the front wheel 14F is supported by the vehicle frame 60 via the stem 27 and the front fork 28.

The top tube 62 is located to the rear of the head tube 61, and extends in a front-rear direction. A front end of the top tube 62 is connected with the head tube 61. A rear end of the top tube 62 is connected with the seat tube 64.

The down tube 63 is located to the rear of the head tube 61, and extends in the front-rear direction. The down tube 63 is located below the top tube 62. A front end of the down tube 63 is connected with the head tube 61. In the example shown in FIG. 1, a front end portion of the down tube 63 is also connected with a front end portion of the top tube 62. A rear end of the down tube 63 is connected with the bracket 65.

The battery unit 26 is attached to the down tube 63. In the example shown in FIG. 1, the battery unit 26 is attached to the inside of the down tube 63. The battery unit 26 supplies electric power to the drive unit 20. The battery unit 26 includes a battery and a control circuit. The battery is a rechargeable battery that is chargeable and dischargeable. The control circuit controls the charge and discharge of the battery, and also monitors the output current, the remaining battery level and the like of the battery.

The seat tube 64 is located to the rear of the top tube 62 and the down tube 63, and extends in the up-down direction. A bottom end of the seat tube 64 is connected with the bracket 65. Namely, the seat tube 64 extends upward from the bracket 65.

In the example shown in FIG. 1, the seat tube 64 is bent at a middle position in the up-down direction. As a result, a bottom portion of the seat tube 64 extends in the up-down direction, whereas a top portion of the seat tube 64 extends in a direction inclined with respect to the up-down direction.

A seat post 29 is inserted into the seat tube 64. The saddle 18 is attached to a top end of the seat post 29.

The bracket 65 is located at a bottom end of the vehicle frame 60. The bracket 65 supports the drive unit 20. The drive unit 20 attached to the vehicle frame 60 generates drive power to be transmitted to a wheel (in this example, the rear wheel 14R). The details of the drive unit 20 will be described below.

The vehicle frame 60 further includes a swing arm 30, a pair of connection arms 303 and a suspension 304. The swing arm 30 includes a pair of chainstays 301 and a pair of seatstays 302.

The pair of chainstays 301 each extend in the front-rear direction. The pair of chainstays 301 are located side by side in the left-right direction. The rear wheel 14R is located between the pair of chainstays 301. The pair of chainstays 301 are located bilaterally symmetrically. Therefore, FIG. 1 shows only the right chainstay 301.

A front end portion of each of the chainstays 301 is attached to the bracket 65. Namely, each chainstay 301 extends rearward from the bracket 65. Each chainstay 301 is swingable, about an axis line extending in the left-right direction, with respect to the bracket 65.

An axle 341 of the rear wheel 14R is non-rotatably attached to a rear end portion of each chainstay 301. Namely, the rear wheel 14R is supported by the pair of chainstays 301 so as to be rotatable about the axle 141. In other words, the rear wheel 14R is supported by the vehicle frame 60. A multi-stage driven sprocket 32 is secured to the rear wheel 14R.

The pair of seatstays 302 each extend in the front-rear direction. The pair of seatstays 302 are located side by side in the left-right direction. The rear wheel 14R is located between the pair of seatstays 302. The pair of seatstays 302 are located bilaterally symmetrically. Therefore, FIG. 1 shows only the right seatstay 302.

A rear end portion of the left seatstay 302 is connected with the rear end portion of the left chainstay 301. A rear end portion of the right seatstay 302 is connected with the rear end portion of the right chainstay 301.

The pair of connection arms 303 each extend in the front-rear direction. The pair of connection arms 303 are located side by side in the left-right direction. The seat tube 64 is located between the pair of connection arms 303. The pair of connection arms 303 are located bilaterally symmetrically. Therefore, FIG. 1 shows only the right connection arm 303.

Each of the connection arms 303 is attached to the seat tube 64. Each connection arm 303 is swingable, about an axis line extending in the left-right direction, with respect to the seat tube 64.

As seen in a side view of the vehicle, a front end of each connection arm 303 is located to the front of the seat tube 64. As seen in a side view of the vehicle, a rear end of each connection arm 303 is located to the rear of the seat tube 64.

A rear end portion of the right connection arm 303 is attached to a front end portion of the right seatstay 302. The right connection arm 303 is swingable, about an axis line extending in the left-right direction, with respect to the right seatstay 302.

A rear end portion of the left connection arm 303 is attached to a front end portion of the left seatstay 302. The left connection arm 303 is swingable, about an axis line extending in the left-right direction, with respect to the left seatstay 302.

The suspension 304 is located to the front of the seat tube 64 and to the rear of the down tube 63. A top end portion of the suspension 304 is attached to the pair of connection arms 303. The suspension 304 is swingable, about an axis line extending in the left-right direction, with respect to the pair of connection arms 303. A bottom end portion of the suspension 304 is attached to the bracket 65. The suspension 304 is swingable, about an axis line extending in the left-right direction, with respect to the bracket 65. The position at which the suspension 304 is attached to the bracket 65 is to the front of the position at which the seat tube 64 is attached to the bracket 65.

A drive sprocket 34 is attached to the drive unit 20 via a support member 33. A chain is wound along the drive sprocket 34 and the driven sprocket 32.

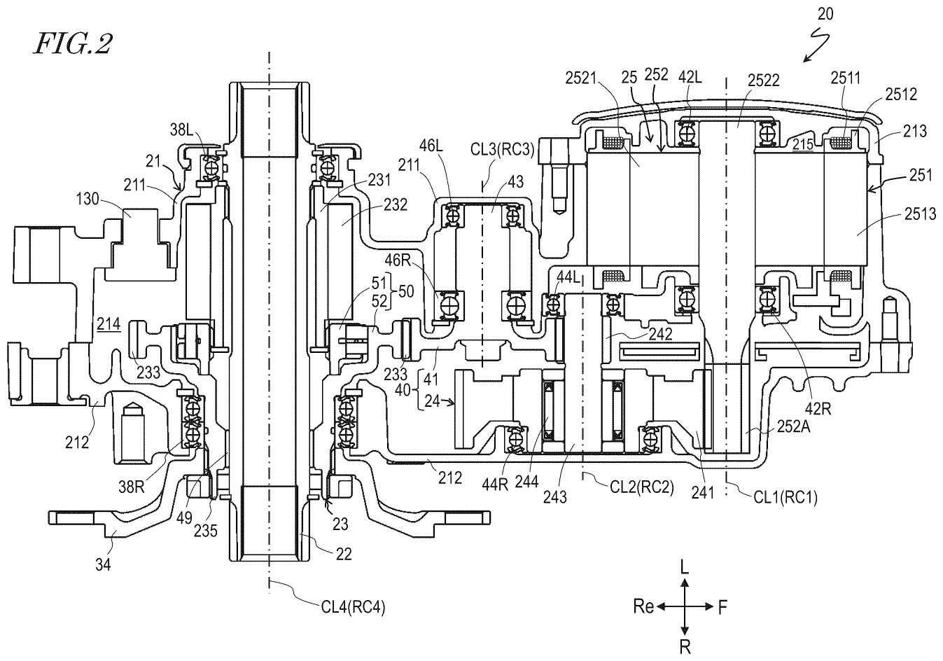

With reference to FIG. 2, an example of structure of the drive unit 20 will be described. FIG. 2 is a cross-sectional view showing an example of internal structure of the drive unit 20.

As shown in FIG. 2, the drive unit 20 includes a housing 21, a pedal crank shaft 22, a rotation shaft 23, a transmission mechanism 40 and an electric motor 25.

First, a structure of the housing 21 according to an example embodiment will be described.

The housing 21 is secured to the bracket 65 (FIG. 1) via a plurality of tightening tools. The housing 21 includes a first case 211, a second case 212, and a cover 213. The first case 211, the second case 212 and the cover 213 are each made of a metal material (e.g., an aluminum alloy).

The first case 211 is fit to the second case 212 from the left in the left-right direction. The first case 211 and the second case 212 are secured to each other via a plurality of tightening tools. As a result, a space 214 is provided between the first case 211 and the second case 212.

The cover 213 is fit to the first case 211 from the left in the left-right direction. The cover 213 and the first case 211 are secured to each other via a plurality of tightening tools. As a result, a space 215 enclosed by the cover 213 is provided to the left of the first case 211. The electric motor 25 is accommodated in the space 215.

Now, a structure of the pedal crank shaft 22 according to an example embodiment will be described.

The pedal crank shaft 22 extends through the housing 21 in the left-right direction of the vehicle, and is rotatably supported by the housing 21. A central axis line CL4 of the pedal crank shaft 22 extends in the left-right direction. As seen in an axial direction of the pedal crank shaft 22 (in a thrust direction), the central axis line CL4 is a rotation center axis RC4 (fourth central axis) of the pedal crank shaft 22. The pedal crank shaft 22 is rotatable, about the central axis line CL4, with respect to the housing 21.

The pedal crank shaft 22 extends through the housing 21 along the fourth central axis RC4, and is supported by the housing 21 so as to be rotatable about the fourth central axis RC4. In the housing 21, the pedal crank shaft 22 is rotatably supported by a pair of bearings 38L and 38R. The bearing 38L is located on the left side in the axial direction, and is secured to the first case 211. The bearing 38R is located on the right side in the axial direction, and is secured to the second case 212.

The pedal crank shaft 22 extends through the rotation shaft 23. The rotation shaft 23 is accommodated in the housing 21. The details of the rotation shaft 23 will be described below. A pair of, namely, left and right, crank arms 35 (see FIG. 1) are attached to the pedal crank shaft 22. A pedal 37 (see FIG. 1) is attached to each of the crank arms 35.

Now, a structure of the electric motor 25 and the transmission mechanism 40 according to an example embodiment will be described.

The electric motor 25 is accommodated in the housing 21, and is secured to the housing 21. The electric motor 25 generates drive power that assists the running of the electrically assisted bicycle 10. The electric motor 25 includes a stator 251 and a rotor 252.

The stator 251 includes a plurality of bobbins 2512, around each of which a coil 2511 is wound. An iron core 2513 is inserted into each of the bobbins 2512. The stator 251 is located in the space 215. In this state, the stator 251 is secured to the first case 211.

The rotor 252 is located inward of the stator 251. A central axis line CL1 of the rotor 252 is parallel or substantially parallel to the central axis line CL4 of the pedal crank shaft 22. Namely, the rotor 252 is located parallel or substantially parallel to the pedal crank shaft 22. As seen in the axial direction of the pedal crank shaft 22, the central axis line CL1 is a rotation center axis RC1 (first central axis) of the rotor 252.

The rotor 252 includes a rotor main body 2521 and an output shaft 2522. An outer circumferential surface of the rotor main body 2521 is magnetized with N poles and S poles alternately in a circumferential direction.

The output shaft 2522 extends through the rotor main body 2521. The output shaft 2522 is secured to the rotor main body 2521. Namely, the output shaft 2522 is rotatable together with the rotor main body 2521.

In the housing 21, the output shaft 2522 is supported by the housing 21 so as to be rotatable about the first central axis RC1. The output shaft 2522 is supported by two bearings 42L and 42R so as to be rotatable, about the central axis line CL1, with respect to the housing 21. The bearing 42L is secured to the cover 213. The bearing 42R is located to the right of the rotor main body 2521, and is secured to the first case 211. The output shaft 2522 extends through the first case 211. A portion of the output shaft 2522 that is located in the space 214 includes an output gear 252A provided therein. The output gear 252A is, for example, a helical gear.

The transmission mechanism 40 is accommodated in the housing 21. Specifically, the transmission mechanism 40 is located in the space 214. The transmission mechanism 40 includes a decelerator 24, an idle gear 41, and a rotation shaft 43. The transmission mechanism 40 transmits a torque of the electric motor 25 to the rotation shaft 23.

The decelerator 24 is rotatably supported by the housing 21, and increases the torque of the output gear 252A of the electric motor 25. The decelerator 24 includes a first transmission gear 241, a second transmission gear 242, and a transmission shaft 243. A central axis line CL2 of the transmission shaft 243 is parallel or substantially parallel to the central axis line CL4 of the pedal crank shaft 22. Namely, the transmission shaft 243 extends parallel or substantially parallel to the central axis line CL4 of the pedal crank shaft 22. As seen in an axial direction of the transmission shaft 243, namely, in the axial direction of the pedal crank shaft 22, the central axis line CL2 is a rotation center axis RC2 (second central axis) of the transmission shaft 243. In the housing 21, the decelerator 24 is supported by the housing 21 so as to be rotatable about the second central axis RC2.

The first transmission gear 241 is located on a right portion of the transmission shaft 243 in the axial direction. A left portion of the transmission shaft 243 is rotatably supported by a bearing 44L. The first transmission gear 241 located on the right portion of the transmission shaft 243 is rotatably supported by a bearing 44R. The transmission shaft 243 and the first transmission gear 241 are supported by the two bearings 44L and 44R so as to be rotatable about the central axis line CL2. The bearing 44L is secured to the first case 211. The bearing 44R is secured to the second case 212.

The first transmission gear 241 is meshed with the output gear 252A of the electric motor 25. With this structure, the drive power generated by the electric motor 25 is transmitted to the first transmission gear 241 from the output gear 252A.

A one-way clutch 244 is located between the first transmission gear 241 and the transmission shaft 243. The one-way clutch 244 couples the transmission shaft 243 and the first transmission gear 241 to each other. The one-way clutch 244 regulates the rotation of the first transmission gear 241 with respect to the transmission shaft 243 to one direction. A rotation force of the output gear 252A acting in such a direction as to rotate the rear wheel 14R (FIG. 1) of the electrically assisted bicycle 10 forward is transmitted to the transmission shaft 243 via the first transmission gear 241, whereas a rotation force of the output gear 252A acting in such a direction as to rotate the rear wheel 14R rearward is not transmitted to the transmission shaft 243. The one-way clutch 244 also prevents a forward rotation force of the pedal crank shaft 22 generated by human power of the rider from being transmitted to the electric motor 25.

The first transmission gear 241 has a diameter larger than that of the output gear 252A of the electric motor 25, and includes teeth of a larger number than that of the output gear 252A. Namely, the first transmission gear 241 is decelerated more than the output gear 252A.

The second transmission gear 242 is made of a metal material (e.g., iron). The second transmission gear 242 is located on the transmission shaft 243. The second transmission gear 242 is located at a position different from that of the first transmission gear 241 in the axial direction of the transmission shaft 243. The second transmission gear 242 has a diameter smaller than that of the first transmission gear 241, and includes teeth of a smaller number than that of the first transmission gear 241. The transmission shaft 243 and the second transmission gear 242 are integral in this example embodiment, but are not limited to this. The second transmission gear 242 may be secured to the transmission shaft 243 by a serration coupling (or by press-fit). The second transmission gear 242 is rotatable together with the transmission shaft 243. The transmission shaft 243 transmits the rotation of the first transmission gear 241 to the second transmission gear 242.

The idle gear 41 is made of a metal material (e.g., iron). The idle gear 41 is located on the rotation shaft 43. The idle gear 41 is secured to the rotation shaft 43 by, for example, a tightening tool, but is not limited to this. The idle gear 41 may be secured to the rotation shaft 43 by a serration coupling (or by press-fit). The idle gear 41 and the rotation shaft 43 may be integral. The idle gear 41 is rotatable together with the rotation shaft 43.

A central axis line CL3 of the rotation shaft 43 is parallel or substantially parallel to the central axis line CL4 of the pedal crank shaft 22. Namely, the rotation shaft 43 extends parallel or substantially parallel to the central axis line CL4 of the pedal crank shaft 22. As seen in an axial direction of the rotation shaft 43, namely, in the axial direction of the pedal crank shaft 22, the central axis line CL3 is a rotation center axis RC3 (third central axis) of the rotation shaft 43. In the housing 21, the idle gear 41 secured by the rotation shaft 43 is supported by the housing 21 so as to be rotatable about the third central axis RC3.

The rotation shaft 43 is supported by two bearings 46L and 46R so as to be rotatable about the central axis line CL3. The bearings 46L and 46R are secured to the first case 211. The idle gear 41 is located closer to the bearing 46R than to the bearing 46L in the axial direction of the rotation shaft 43. The idle gear 41 is meshed with the second transmission gear 242 of the decelerator 24. With this structure, the output torque of the electric motor 25 increased by the decelerator 24 is transmitted to the idle gear 41.

Now, a structure of the vicinity of the pedal crank shaft 22 will be described.

The rotation shaft 23 is coaxial with the pedal crank shaft 22, and is rotatable together with the pedal crank shaft 22. The rotation shaft 23 includes a coupling shaft 231 and a one-way clutch 50.

The coupling shaft 231 has a cylindrical shape. The pedal crank shaft 22 is inserted into the coupling shaft 231. The coupling shaft 231 is coaxial with the pedal crank shaft 22.

A left end portion of the coupling shaft 231 is coupled with the pedal crank shaft 22 by a serration coupling or the like. As a result, regardless of whether the pedal crank shaft 22 is rotated forward or rearward, the coupling shaft 231 is rotated together with the pedal crank shaft 22.

A torque detection device 232 is located around the coupling shaft 231. The torque detection device 232 is supported by the coupling shaft 231, and is not rotatable with respect to the first case 211. The torque detection device 232 detects a torque generated in the coupling shaft 231 when the driver steps on the pedals. The torque detection device 232 includes, for example, a magnetostrictive torque sensor. The torque detection device 232 outputs a signal in accordance with the detected torque to a control circuit mounted on a board described below. The control circuit refers to the torque detected by the torque detection device 232 to learn the state of the pedaling performed by the driver and to control the electric motor 25.

The one-way clutch 50 is located to the right of the torque detection device 232 in the axial direction of the pedal crank shaft 22. The one-way clutch 50 is located on the pedal crank shaft 22 via the coupling shaft 231. The one-way clutch 50 is coaxial with the pedal crank shaft 22. The one-way clutch 50 includes an inner member 51 and an outer member 52.

The inner member 51 of the one-way clutch 50 has a cylindrical shape. A right portion of the coupling shaft 231 is inserted into the inner member 51. The inner member 51 is coaxial with the coupling shaft 231. In this state, the right portion of the coupling shaft 231 is coupled with the inner member 51 by a serration coupling or the like. As a result, regardless of whether the coupling shaft 231 is rotated forward or rearward, the inner member 51 is rotated together with the coupling shaft 231. Namely, regardless of whether the pedal crank shaft 22 is rotated forward or rearward, the inner member 51 is rotated together with the pedal crank shaft 22. The coupling shaft 231 and the inner member 51 act as a crank rotation input shaft that is rotatable integrally with the pedal crank shaft 22.

The outer member 52 of the one-way clutch 50 has a cylindrical shape. The pedal crank shaft 22 is inserted into the outer member 52. A slide bearing 49 is located between the outer member 52 and the pedal crank shaft 22. With this structure, the outer member 52 is rotatable coaxially with the pedal crank shaft 22.

A latchet mechanism as a one-way clutch mechanism is provided between the outer member 52 and the inner member 51. With this structure, a forward rotation force of the inner member 51 is transmitted to the outer member 52, whereas a rearward rotation force of the inner member 51 is not transmitted to the outer member 52. A forward rotation force of the outer member 52 generated by the rotation of the electric motor 25 is not transmitted to the inner member 51.

The outer member 52 is supported by the bearing 38R so as to be rotatable, about the central axis line CL4 of the pedal crank shaft 22, with respect to the housing 21. The outer member 52 extends through the second case 212. The drive sprocket 34 is attached to a portion of the outer member 25 that is outward of (to the right of) the housing 21.

The outer member 52 includes a driven gear 233. The driven gear 233 is located on the pedal crank shaft 22 via the one-way clutch 50 and the coupling shaft 231. The driven gear 233 is meshed with the idle gear 41. The driven gear 233 has a diameter larger than that of each of the second transmission gear 242 and the idle gear 41, and includes teeth of a larger number than that of each of the second transmission gear 242 and the idle gear 41. Namely, the driven gear 233 is rotated at a rotation rate lower than the rotation rate of each of the second transmission gear 242 and the idle gear 41. The idle gear 41 is meshed with each of the second transmission gear 242 and the driven gear 233, so that the output torque of the electric motor 25 increased by the decelerator 24 may be transmitted to the driven gear 233 via the single idle gear 41.

The outer member 52 transmits a synthesized power of the human power (pedal effort) transmitted to the coupling shaft 231 and assist drive power of the electric motor 25 to the drive sprocket 34. The outer member 52 realizes a synthesized power output shaft 235, which synthesizes the human power that is input via the one-way clutch 50 and the assist drive power that is input via the driven gear 233 and outputs the synthesized power. The synthesized power output shaft 235 rotates coaxially with the pedal crank shaft 22. The synthesized power output shaft 235 is included in the rotation shaft 23.

Now, boards and wires located in the drive unit 20 according to an example embodiment will be described.

As described above, many components are located in the drive unit 20. Therefore, the boards in which electric circuits causing the electric motor 25 to operate and the wires are restricted in the positional arrangement thereof, like the other components. In an example embodiment, the boards and the wires are configured so as to be positionally arranged with an increased degree of freedom in the drive unit 20, so that the other components may be positionally arranged in the drive unit 20 with a higher degree of freedom and also the drive unit 20 may be made smaller.

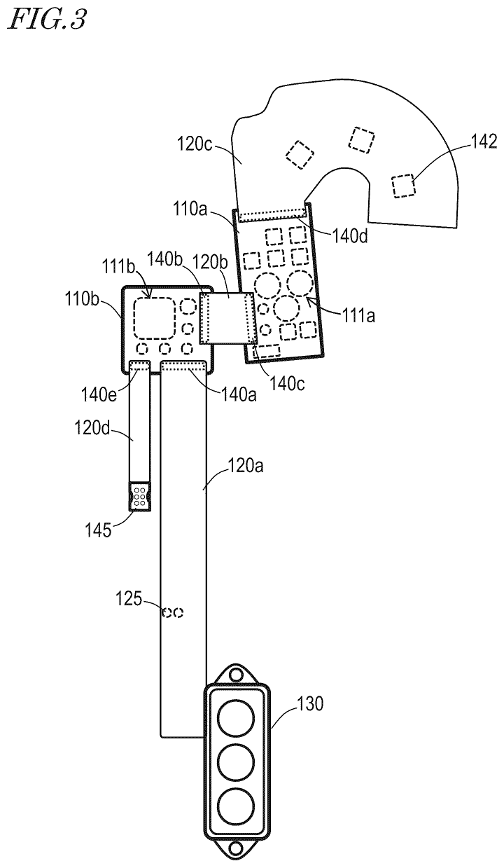

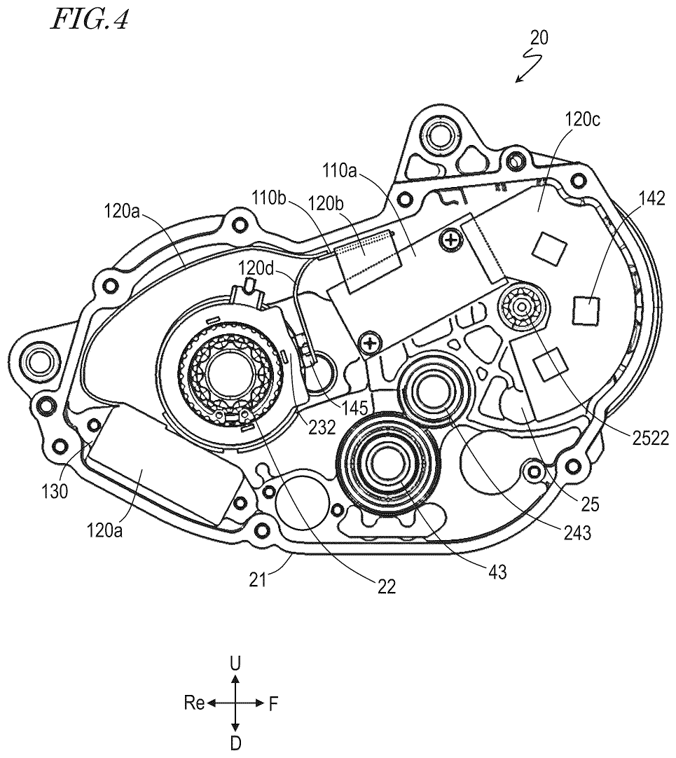

FIG. 3 shows an example of the boards and the wires according to an example embodiment. FIG. 4 shows an example of internal structure of the drive unit 20, in which the boards and the wires according to an example embodiment are located. FIG. 4 shows the inside of the drive unit 20 as seen from the right side thereof. In this example embodiment, flexible printed circuits (FPC) are used as at least a portion of the wires that electrically connect the components to each other.

In this example, the drive unit 20 includes a power supply circuit board 110a, a control circuit board 110b, flexible printed circuits 120a through 120d, and an external device connector 130.

The power supply circuit board 110a and the control circuit board 110b are each a rigid board. The power supply circuit board 110a includes a power supply circuit 111a, which outputs electric power to drive the electric motor 25. The power supply circuit 111a includes, for example, a smoothing circuit to smooth a DC voltage that is output from the battery unit 26 (FIG. 1) and an inverter circuit to generate a motor driving current. The power supply circuit 111a generates, for example, a three-phase AC motor driving current. The control circuit board 110b includes a control circuit 111b to control an operation of the power supply circuit 111a. The external device connector 130 is a connector electrically connecting the drive unit 20 and an external device (e.g., the battery unit 26, an operation panel, or the like) to each other.

The control circuit board 110b and the external device connector 130 are electrically connected with each other via the flexible printed circuit 120a.

The control circuit board 110b and the flexible printed circuit 120a are electrically connected with each other via, for example, a connector 140a. The connector 140a is, for example, a board-to-board connector or an FPC connector. Use of the board-to-board connector may decrease the thickness of a connection portion. Each of connectors 140b through 140e described below may also be a board-to-board connector or an FPC connector.

The flexible printed circuit 120a expands so as to cover a rear surface of the external device connector 130 from which a plurality of pins extend. The external device connector 130 may be directly mounted on the flexible printed circuit 120a. Alternatively, the external device connector 130 may be electrically connected with the flexible printed circuit 120a via a connector.

The control circuit board 110b and the power supply circuit board 110a are electrically connected with each other via the flexible printed circuit 120b. The control circuit board 110b and the flexible printed circuit 120b are electrically connected with each other via, for example, the connector 140b. The power supply circuit board 110a and the flexible printed circuit 120b are electrically connected with each other via, for example, the connector 140c. The power supply circuit 111a and the control circuit 111b may send or receive signals to or from each other via the flexible printed circuit 120b.

The control circuit 111b may send or receive signals to or from an external device via the external device connector 130 and the flexible printed circuit 120a. An output current of the battery unit 26 is supplied to the power supply circuit 111a via the external device connector 130, the flexible printed circuit 120a, the control circuit board 110b and the flexible printed circuit 120b. The power supply circuit 111a generates and outputs a motor driving current that drives the electric motor 25.

The power supply circuit board 110a and the electric motor 25 are electrically connected with each other via the flexible printed circuit 120c. The power supply circuit board 110a and the flexible printed circuit 120c are electrically connected with each other via, for example, the connector 140d. Busbars are electrically connected with the stator 251 of the electric motor 25. The flexible printed circuit 120c is electrically connected with the busbars via connectors 142. The motor driving current that is output from the power supply circuit 111a is supplied to the stator 251 via the flexible printed circuit 120c and the busbars, and generates a magnetic force in the stator 251.

The control circuit board 110b and the torque detection device 232 are electrically connected with each other via the flexible printed circuit 120d. The control circuit board 110b and the flexible printed circuit 120d are electrically connected with each other via, for example, the connector 140e. The flexible printed circuit 120d is provided with a connector 145. The flexible printed circuit 120d is electrically connected with the torque detection device 232 via the connector 145. The connector 145 may be directly mounted on the flexible printed circuit 120d. Alternatively, the connector 145 may be electrically connected with the flexible printed circuit 120d via a connector. The control circuit board 110b may receive an output signal from the torque detection device 232 via the flexible printed circuit 120d. In the case where the drive unit 20 includes a rotation detection device to detect the rotation of the pedal crank shaft 22, the control circuit board 110b may receive an output signal from the rotation detection device via the flexible printed circuit 120d.

In the example shown in FIG. 4, the control circuit board 110b and the flexible printed circuit 120a are mainly located in a top space in the housing 21. The power supply circuit board 110a and the flexible printed circuit 120c are mainly located in a right space in the housing 21. The flexible printed circuits have a high degree of freedom of bending. Therefore, as shown in FIG. 4, the flexible printed circuit 120b may be bent at a large curvature in a small space.

The flexible printed circuit 120a extending from the control circuit board 110b is bent at about 90 degrees at a rear bottom position in the housing 21 and is connected with the external device connector 130. In this example, as shown in FIG. 2, the external device connector 130 is exposed outside through an opening provided in a left wall of the housing 21. A connector extending from an external device is connected with external device connector 130.

In an example embodiment, the control circuit board 110b and the external device connector 130 are electrically connected with each other via the flexible printed circuit 120a. In general, flexible printed circuits are thinner than, and have a higher degree of freedom of bending than, round wires. The control circuit board 110b and the external device connector 130 are electrically connected with each other via the flexible printed circuit 120a, and therefore, may be positionally arranged in the housing 21 with a higher degree of freedom. In addition, the other components may also be positionally arranged in the housing 21 with a higher degree of freedom.

In an example embodiment, the flexible printed circuits, which are used as wires, are not twisted or bent unlike the round wires, which have a large dimensional tolerance. Therefore, the space required for the wires may be smaller, and thus the drive unit 20 may be smaller. Such a decrease in the size of the drive unit 20 allows the components around the drive unit 20 in the electrically assisted bicycle 10 to be positionally arranged with a higher degree of freedom.

In an example embodiment, the power supply circuit board 110a and the control circuit board 110b are separately provided. With this structure, the control circuit 111b may be located far away from the power supply circuit 111a, which generates a large amount of heat. This may improve the stability of the control of the operation of the electric motor 25, and permits the power supply circuit 111a to generate a larger amount of heat.

The power supply circuit board 110a and the control circuit board 110b are electrically connected with each other via the flexible printed circuit 120b, and therefore, may be positionally arranged in the housing 21 with a higher degree of freedom.

As shown in FIG. 3, the control circuit board 110b may be smaller than the power supply circuit board 110a. Therefore, the control circuit board 110b may be located in a relatively small space in the housing 21. The power supply circuit 111a and the control circuit 111b are provided in separate circuit boards, so that relatively small spaces in the housing 21 may be effectively used.

In the example shown in FIG. 3, the flexible printed circuit 120a is provided with noise suppressors 125. The noise suppressors 125 include, for example, a capacitor and/or an inductor. The flexible printed circuits are used as wires so that the noise suppressors 125 may be easily located on the wires at such positions as to effectively reduce or prevent noise. This may decrease the number of the noise suppressors to be located on the rigid boards such as the control circuit board 110b and the like, and also decrease the size of the rigid boards.

Now, an example of a method to connect the external device connector 130 and the flexible printed circuit 120a to each other will be described.

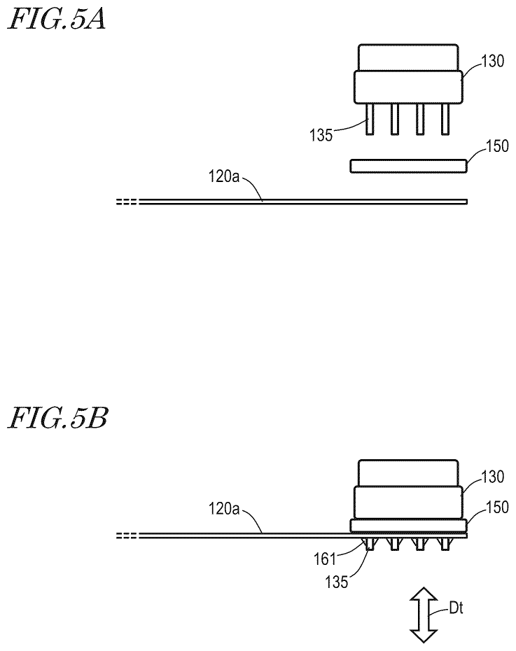

FIG. 5A and FIG. 5B show an example of a method to connect the external device connector 130 and the flexible printed circuit 120a to each other. FIG. 5A shows the external device connector 130, a reinforcing plate 150 and the flexible printed circuit 120a. FIG. 5B shows the external device connector 130 the flexible printed circuit 120a connected to each other with the reinforcing plate 150 being held therebetween. In this example, the reinforcing plate 150 is between the flexible printed circuit 120a and the external device connector 130 in a thickness direction Dt of the flexible printed circuit 120a at a location where the flexible printed circuit 120a and the external device connector 130 are stacked on each other. The reinforcing plate 150 is, for example, a rigid board, but is not limited to this. The reinforcing plate 150 may be bonded with the flexible printed circuit 120a and/or the external device connector 130.

A plurality of pins 135 extending from the external device connector 130 pass through the reinforcing plate 150 and the flexible printed circuit 120a. The flexible printed circuit 120a and the pins 135 of the external device connector 130 are electrically connected with each other by, for example, solder 161. Instead of the solder 161, an anisotropic conductive film or an anisotropic conductive paste may be used.

The external device connector 130 is directly mounted on the flexible printed circuit 120a with no use of a connector connecting the external device connector 130 and the flexible printed circuit 120a to each other, so that the thickness of the connection portion of the external device connector 130 and the flexible printed circuit 120a may be decreased. Use of the reinforcing plate 150 may increase the strength of the connection portion of the external device connector 130 and the flexible printed circuit 120a.

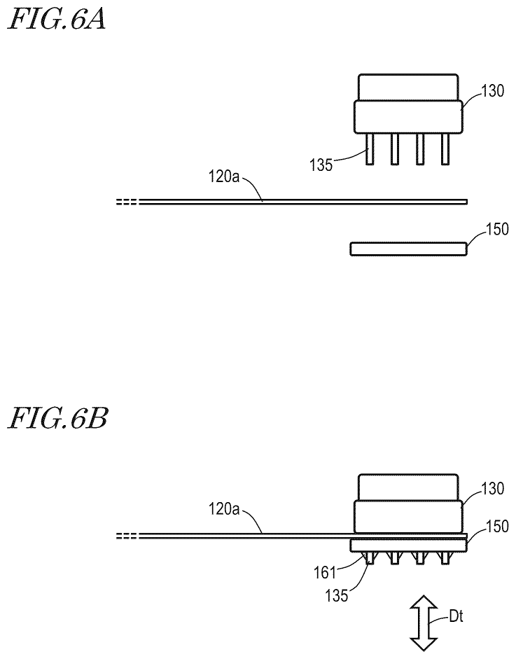

FIG. 6A and FIG. 6B show another example of a method to connect the external device connector 130 and the flexible printed circuit 120a to each other. FIG. 6A shows the external device connector 130, the flexible printed circuit 120a and the reinforcing plate 150. FIG. 6B shows the reinforcing plate 150 located on a surface of the flexible printed circuit 120a opposite to a surface of the flexible printed circuit 120a connected with the external device connector 130, the reinforcing plate 150 being located on the surface in the direction Dt of the flexible printed circuit 120a at the position where the flexible printed circuit 120a and the external device connector 130 are stacked on each other.

The pins 135 of the external device connector 130 extend through the flexible printed circuit 120a and the reinforcing plate 150. The flexible printed circuit 120a and the pins 135 of the external device connector 130 are electrically connected with each other by, for example, the solder 161. Instead of the solder 161, an anisotropic conductive film or an anisotropic conductive paste may be used. For example, an anisotropic conductive film or an anisotropic conductive paste located between the external device connector 130 and the flexible printed circuit 120a may be used to electrically connect the flexible printed circuit 120a and the pins 135 to each other.

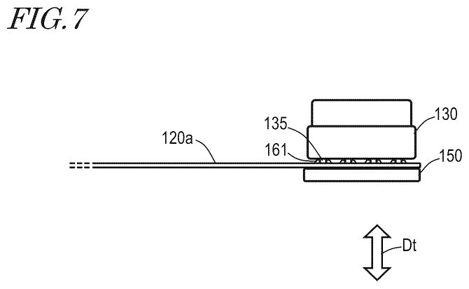

FIG. 7 shows still another example of a method to connect the external device connector 130 and the flexible printed circuit 120a to each other. In the example shown in FIG. 7, the external device connector 130 is electrically connected with the flexible printed circuit 120a by surface mounting. For the connection, the solder 161, an anisotropic conductive film or an anisotropic conductive paste may be used. The reinforcing plate 150 is located on a surface of the flexible printed circuit 120a opposite to a surface of the flexible printed circuit 120a connected with the external device connector 130. In this example, the reinforcing plate 150 does not need to be a rigid board. Any board providing a necessary strength may be used as the reinforcing plate 150.

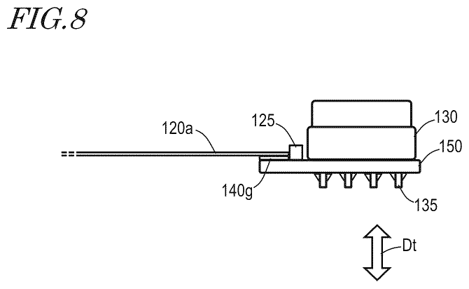

In the example shown in FIG. 3, the noise suppressors 125 are provided on the flexible printed circuit 120a. Alternatively, the noise suppressors 125 may be provided on the reinforcing plate 150. FIG. 8 shows a noise suppressor 125 provided on the reinforcing plate 150. In the example shown in FIG. 8, the reinforcing plate 150 is a rigid board, and is electrically connected with the flexible printed circuit 120a via a connector 140g. The connector 140g is, for example, a board-to-board connector or an FPC connector. The noise suppressor 125 is located in the vicinity of, for example, the connector 140g. The rigid board 150 having the noise suppressor 125 provided thereon is used so that the connection portion of the flexible printed circuit 120a and the external device connector 130 may have an increased strength and also improved tolerance against noise. The noise suppressor 125 may be provided on the reinforcing plate 150 shown in each of FIG. 5 through FIG. 7.

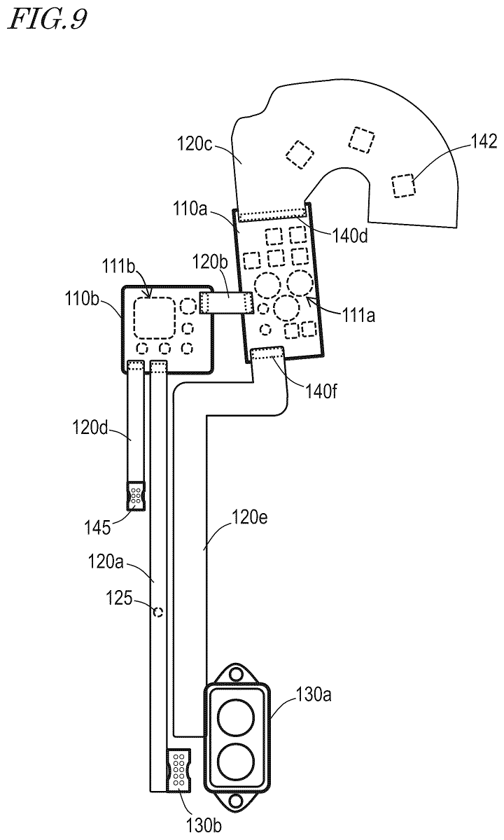

Now, another example of the flexible printed circuit 120 and the connector 130 will be described. FIG. 9 shows another example of the flexible printed circuit 120 and the connector 130.

In the example shown in FIG. 9, a connector 130a receiving an output current from the battery unit 26, and a connector 130b sending or receiving control signals between the control circuit board 110b and an external device, are provided separately. The connector 130b is electrically connected with the flexible printed circuit 120a. The control circuit board 110b is electrically connected with the external device via the flexible printed circuit 120a and the connector 130b.

The connector 130a is electrically connected with a flexible printed circuit 120e. The flexible printed circuit 120e and the power supply circuit board 110a are electrically connected with each other via a connector 140f. The connector 140f is, for example, a board-to-board connector or an FPC connector. An output current from the battery unit 26 is supplied to the power supply circuit 111a via the external device connector 130a and the flexible printed circuit 120e.

The external device connector 130 tends to be enlarged in the case of having many functions in a single body. The flexible printed circuit 120 also tends to be enlarged in the case of having many functions in a single body. The external device connector 130 and the flexible printed circuit 120, each of which tends to be enlarged in the case of having many functions in a single body, are divided into a plurality of portions, so that each of such portions of the external device connector 130 and the flexible printed circuit 120 may be smaller and located in a smaller space in the housing 21.

The external device connector 130b and the flexible printed circuit 120a for the control circuit board 110b may be easily smaller and each located in a relatively small space in the housing 21. Therefore, relatively small spaces in the housing 21 may be effectively used.

Example embodiments of the present invention have been described above. The present invention is not limited to the above-described example embodiments. For example, in the above-described example embodiments, the electrically assisted bicycle including the suspension is described as an example. The present invention is preferably applicable also to an electrically assisted bicycle with no suspension.

In the above-described example embodiments, the drive unit 20 (FIG. 2) includes four shafts, namely, the output shaft 2522, the transmission shaft 243, the rotation shaft 43 and the pedal crank shaft 22. The number of the shafts is not limited to four. The present invention is also applicable to a drive unit including five or more shafts. For example, the present invention is applicable to a drive unit in which a gear is provided between the output gear 252A of the electric motor 25 and the first transmission gear 241 of the decelerator 24 and a torque is transmitted from the output gear 252A to the first transmission gear 241 via the above-mentioned gear.

In the above-described example embodiments, the drive unit 20 includes the idle gear 41. The present invention is also applicable to the drive unit 20 without the idle gear 41.

In the above-described example embodiments, the entirety of the electric motor 25 is accommodated in the housing 21. The structure of the housing 21 is not limited to this. Only a portion of the electric motor 25 may be accommodated in the housing 21. For example, a left portion of the first case 211 may have an opening through which the electric motor 25 may extend, and the electric motor 25 may be attached such that a portion thereof is located in the housing 21 through the opening. In this case, the opening may be provided with a dust-proof and waterproof cover.

The cover 213 (FIG. 2) may be a portion of the housing 21, and may be included in the housing 21. The cover 213 may have such a shape as to cover a side surface of the electric motor 25, and the electric motor 25 may be supported by the cover 213. The electric motor 25 being supported by the cover 213 includes the electric motor 25 supported by the housing 21.

In the above-described example embodiments, the electrically assisted bicycle with two wheels is described as an example of the electrically assisted vehicle. The present invention is not limited to this. For example, the present invention is also applicable to an electrically assisted vehicle with three or more wheels.

In the above-described example embodiments, the drive wheel to which the human power generated by the rider stepping on the pedals and the assist power generated by the motor are transmitted is the rear wheel. The present invention is not limited to this. The human power and the assist power may be transmitted to the front wheel, or both of the front wheel and the rear wheel, in accordance with the type of the electrically assisted bicycle.

In the above-described example embodiments, the vehicle is the electrically assisted bicycle, but alternatively, may be a vehicle other than the electrically assisted bicycle. The present invention is preferably applicable to any vehicle in which the drive unit is required to have a decreased size.

Illustrative example embodiments of the present invention have been described above. This specification discloses drive unit for electrically assisted bicycles as described below.

A drive unit 20 usable in an electrically assisted bicycle 10 includes an electric motor 25, a housing 21 accommodating a portion or an entirety of the electric motor 25, a pedal crank shaft 22 extending through the housing 21 and rotatably supported by the housing 21 a transmission mechanism 40 to transmit a torque of the electric motor 25, a rigid board 110 including an electric circuit 111 to cause the electric motor 25 to operate, a flexible printed circuit 120 to electrically connect the rigid board 110 and another predetermined component 110, 130 in addition to the rigid board 110 to each other.

According to an example embodiment of the present invention, the rigid board 110 including the electric circuit 111 to cause the electric motor 25 to operate and the predetermined component 110, 130 are electrically connected with each other by the flexible printed circuit 120. In general, the flexible printed circuit 120 is thinner than, and has a higher degree of freedom of bending than, a round wire. The rigid board 110 and the predetermined component 110, 130 are electrically connected with each other by the flexible printed circuit 120, and therefore, may be positionally arranged in the housing 21 with a higher degree of freedom. In addition, the other components may also be positionally arranged in the housing 21 with a higher degree of freedom.

The flexible printed circuit 120, which is used as a wire, is not twisted or bent unlike a round wire, which has a large dimensional tolerance. Therefore, the space required for the wire may be smaller, and thus the drive unit 20 may be smaller.

In the drive unit 20, the predetermined component 110, 130 includes an external device connector 130 to electrically connect the drive unit 20 and an external device to each other, and the flexible printed circuit 120 to electrically connect the rigid board 110 and the external device connector 130 to each other.

With this structure, the rigid board 110 and the external device connector 130 may be positionally arranged in the housing 21 with a higher degree of freedom.

In the drive unit 20, the predetermined component 110, 130 includes another rigid board 110 in addition to the rigid board 110, and wherein the flexible printed circuit 120 electrically connects the rigid board 110 and the another rigid board 110 to each other.

With this structure, the plurality of rigid boards 110 may be positionally arranged in the housing 21 with a higher degree of freedom.

In the drive unit 20, one of the rigid board 110 and the another rigid board 110 is a power supply circuit board 110a including a power supply circuit 111a to output electric power to drive the electric motor 25, and the other of the rigid board 110 and the another rigid board 110 is a control circuit board 110b including a control circuit 111b to control an operation of the power supply circuit 111a.

The control circuit 111b may be located far away from the power supply circuit 111a, which generates a large amount of heat. This may improve the stability of the control of the operation of the electric motor 25, and permit the power supply circuit 111a to generate a larger amount of heat.

The power supply circuit board 110a and the control circuit board 110b are electrically connected with each other by the flexible printed circuit 120, and therefore, may be positionally arranged in the housing 21 with a higher degree of freedom.

In the drive unit 20, the control circuit board 110b is smaller than the power supply circuit board 110a.

The control circuit board 110b may be located in a relatively small space in the housing 21. The power supply circuit 111a and the control circuit 111b are included in separate boards, so that relatively small spaces in the housing 21 may be effectively used.

In the drive unit 20, the predetermined component 110, 130 includes an external device connector 130 to electrically connect the drive unit 20 and an external device to each other, the drive unit 20 further includes another rigid board 110 in addition to the rigid board 110, another external device connector 130 in addition to the external device connector 130, and another flexible printed circuit 120 in addition to the flexible printed circuit 120. The flexible printed circuit 120 electrically connects the rigid board 110 and the external device connector 130 to each other, and the another flexible printed circuit 120 electrically connects the another rigid board 110 and the another external device connector 130 to each other.

The external device connector 130 and the flexible printed circuit 120, each of which tends to be enlarged in the case of having many functions in a single body, are divided into a plurality of portions, so that each of such portions of the external device connector 130 and the flexible printed circuit 120 may be smaller and located in a smaller space in the housing 21.

In the drive unit 20, one of the rigid board 110 and the another rigid board 110 is a power supply circuit board 110a including a power supply circuit 111a to output electric power to drive the electric motor 25, and the other of the rigid board 110 and the another rigid board 110 is a control circuit board 110b including a control circuit 111b to control an operation of the power supply circuit 111a.

The external device connector 130 and the flexible printed circuit 120 for the control circuit board 110b may easily be smaller and each located in a relatively small space in the housing 21. Therefore, relatively small spaces in the housing 21 may be effectively used.

The drive unit 20, a reinforcing plate 150 may be between the flexible printed circuit 120 and the external device connector 130 in a thickness direction Dt of the flexible printed circuit 120 at a location where the flexible printed circuit 120 and the external device connector 130 are stacked on each other.

A connector is not used to connect the flexible printed circuit 120 and the external device connector 130 so that the thickness of the connection portion of the flexible printed circuit 120 and the external device connector 130 may be decreased.

Use of the reinforcing plate 150 may increase the strength of the connection portion of the flexible printed circuit 120 and the external device connector 130.

The drive unit 20 may include a reinforcing plate 150 provided on a surface of the flexible printed circuit 120 opposite to a surface of the flexible printed circuit 120 connected with the external device connector 130 in a thickness direction of the flexible printed circuit 120 at a location where the flexible printed circuit 120 and the external device connector 130 are stacked on each other.

Use of the reinforcing plate 150 may increase the strength of the connection portion of the flexible printed circuit 120 and the external device connector 130.

In the drive unit 20, the external device connector 130 includes pins 135 extending through the reinforcing plate 150.

With this structure, the flexible printed circuit 120 and the external device connector 130 may be electrically connected with each other with no wire bypassing the reinforcing plate 150.

The pins 135 of the external device connector 130 extends through the reinforcing plate 150 so that the reinforcing plate 150 may be reduced or prevented from being positionally shifted.

In the drive unit 20, the flexible printed circuit 120 and the external device connector 130 are electrically connected with each other by at least one of solder 161, an anisotropic conductive film or an anisotropic conductive paste.

The flexible printed circuit 120 and the external device connector 130 are directly mounted on each other with no use of a connector connecting the flexible printed circuit 120 and the external device connector 130 to each other, so that the thickness of the connection portion of the flexible printed circuit 120 and the external device connector 130 may be decreased.

The drive unit 20 may further include a noise suppressor 125 provided on the flexible printed circuit 120.

The flexible printed circuit 120 is used as a wire, so that the noise suppressor 125 may be easily located on the wire at such a position as to effectively reduce or prevent noise. This may decrease the number of the noise suppressors to be located on the rigid board 110, and also decrease the size of the rigid board 110.

In the drive unit 20, the reinforcing plate 150 is a rigid board 110 provided with a noise suppressor 125.

With this structure, the connection portion of the flexible printed circuit 120 and the external device connector 130 may have an increased strength and also improved tolerance against noise.

An electrically assisted bicycle 10 according to an example embodiment of the present invention includes the drive unit 20 including any of the features described above.

The drive unit 20 is smaller so that the components around the drive unit 20 may be positionally arranged in the electrically assisted bicycle 10 with a higher degree of freedom.

Example embodiments of the present invention are especially useful in the fields of electrically assisted vehicles and drive units mountable on the electrically assisted vehicles.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A drive unit usable in an electrically assisted bicycle, the drive unit comprising:
an electric motor;
a housing accommodating a portion or an entirety of the electric motor;
a pedal crank shaft extending through the housing and rotatably supported by the housing;
a transmission to transmit a torque of the electric motor;
a rigid board including an electric circuit to cause the electric motor to operate; and
a flexible printed circuit to electrically connect the rigid board and another predetermined component in addition to the rigid board to each other.

2. The drive unit of claim 1, wherein
the predetermined component includes an external device connector to electrically connect the drive unit and an external device to each other; and
the flexible printed circuit electrically connects the rigid board and the external device connector to each other.

3. The drive unit of claim 1, wherein
the predetermined component includes another rigid board in addition to the rigid board; and
the flexible printed circuit electrically connects the rigid board and the another rigid board to each other.

4. The drive unit of claim 3, wherein
one of the rigid board and the another rigid board is a power supply circuit board including a power supply circuit to output electric power to drive the electric motor; and
the other of the rigid board and the another rigid board is a control circuit board including a control circuit to control an operation of the power supply circuit.

5. The drive unit of claim 4, wherein the control circuit board is smaller than the power supply circuit board.

6. The drive unit of claim 1, wherein
the predetermined component includes an external device connector to electrically connect the drive unit and an external device to each other;
the drive unit further includes:
another rigid board in addition to the rigid board;
another external device connector in addition to the external device connector; and
another flexible printed circuit in addition to the flexible printed circuit;
the flexible printed circuit electrically connects the rigid board and the external device connector to each other; and
the another flexible printed circuit electrically connects the another rigid board and the another external device connector to each other.

7. The drive unit of claim 6, wherein
one of the rigid board and the another rigid board is a power supply circuit board including a power supply circuit to output electric power to drive the electric motor; and
the other of the rigid board and the another rigid board is a control circuit board including a control circuit to control an operation of the power supply circuit.

8. The drive unit of claim 2, further comprising a reinforcing plate between the flexible printed circuit and the external device connector in a thickness direction of the flexible printed circuit, at a location where the flexible printed circuit and the external device connector are stacked on each other.

9. The drive unit of claim 2, further comprising a reinforcing plate on a surface of the flexible printed circuit opposite to a surface of the flexible printed circuit connected with the external device connector in a thickness direction of the flexible printed circuit, at a location where the flexible printed circuit and the external device connector are stacked on each other.

10. The drive unit of claim 8, wherein the external device connector includes pins extending through the reinforcing plate.

11. The drive unit of claim 2, wherein the flexible printed circuit and the external device connector are electrically connected with each other by at least one of solder, an anisotropic conductive film, or an anisotropic conductive paste.

12. The drive unit of claim 1, further comprising a noise suppressor on the flexible printed circuit.

13. The drive unit of claim 8, wherein the reinforcing plate is a rigid board including a noise suppressor.

14. An electrically assisted bicycle comprising:
the drive unit of claim 1.
